(19) United States
(12) Patent Application Publication
(10) Pub. No.: US 2013/0128447 A1
(43) Pub. Date: May 23, 2013

(54) ELECTRONIC DEVICE WITH MOUNTING APPARATUS FOR HARD DISK DRIVE

(71) Applicant: LEI LIU, Shenzhen City (CN)

(72) Inventor: LEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/330,550

(22) Filed: Dec. 19, 2011

(30) Foreign Application Priority Data
Nov. 18, 2011 (CN) 201110367869.6

(51) Int. Cl. H05K 7/14

(52) U.S. Cl. 361/679.33; 248/222.11

(57) ABSTRACT

A mounting apparatus for a hard disk drive includes a bracket received in an expansion bay of an electronic device, a resilient latching member, and a connector. The bracket includes two opposite positioning plates and an end plate connected between rear ends of the positioning plates. The bracket defines a receiving space for receiving the hard disk drive. The latching member includes a first end mounted to an outer side surface of one of the positioning plates, and a second end detachably latched to the hard disk drive. The connector is fixed to the end plate to connect the hard disk drive.

### BACKGROUND

1. Technical Field

The present disclosure relates to electronic devices, and particularly, to an electronic device with an apparatus for mounting a hard disk drive.

2. Description of Related Art

Personal computers often include a plurality of expansion bays for fixing compact disk read-only memories (CD-ROMs) or other components therein. Some of the expansion bays may be unused or idle.

A mobile external hard disk drive is electrically connected to the motherboard of a computer through a universal serial bus. The mobile hard disk usually occupies a table space, and is supported on a table. However, since some of the expansion bays are often unused and available, making use of one of the unused expansion bays to mount an external hard disk drive would be desirable.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of an electronic device together with a hard disk drive, wherein the electronic device includes a mounting apparatus.

FIG. 2 is an exploded, cutaway, isometric view of the mounting apparatus and a hard disk drive of FIG. 1.

FIG. 3 is similar to FIG. 2, but viewed from another perspective.

FIG. 4 is an assembled, isometric view of the mounting apparatus of FIG. 2.

FIGS. 5-6 are assembled, isometric views of FIG. 1, but respectively show different processes of the hard disk drive assembly.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

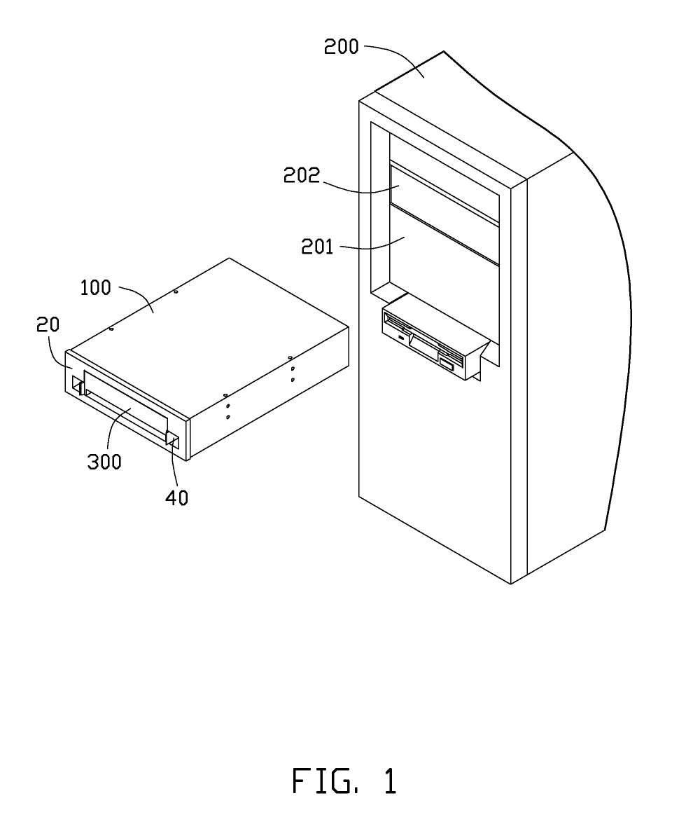

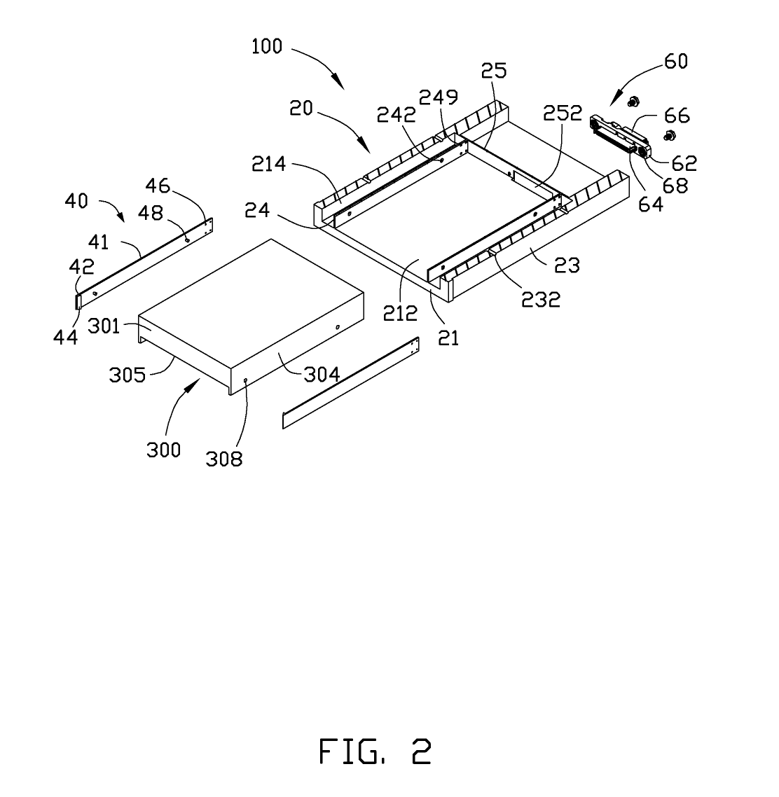

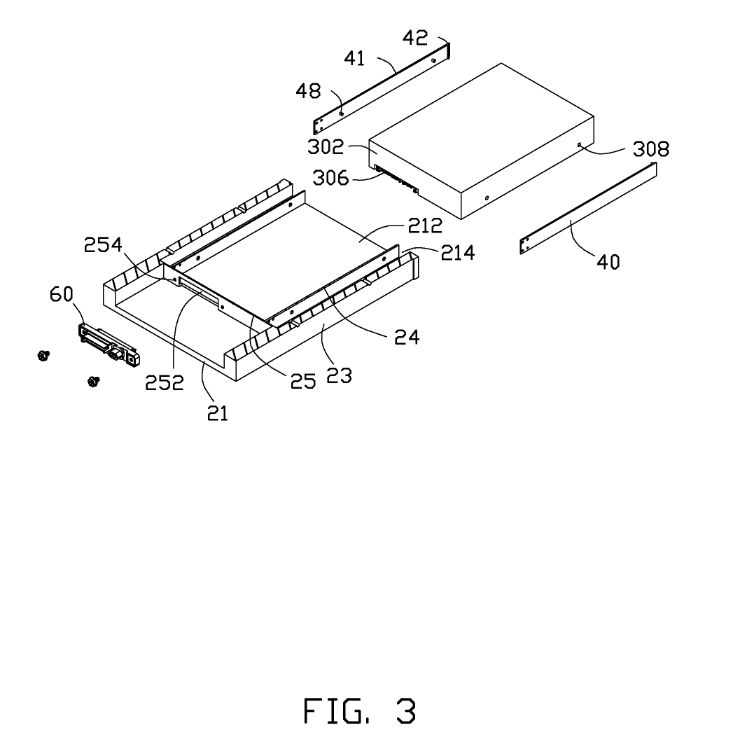

Referring to FIGS. 1-3, an exemplary embodiment of an electronic device includes a casing 200, a mounting apparatus 100, and a hard disk drive 300 detachably mounted in the mounting apparatus 100. The mounting apparatus 100 includes a bracket 20, two resilient latching members 40, and a switching member 60. In the embodiment, the electronic device is a computer.

The casing 200 is a rectangular shell and defines a plurality of expansion bays 202 for fixing compact disk read-only memory (CD-ROM) drives therein. The casing 200 includes a front panel 201. The expansion bays 202 extend through the front panel 201.

The hard disk drive 300 includes a front wall 301 defining an operation slot 305, a rear wall 302 mounting a connector 306, and two opposite side plates 304 respectively defining two connecting holes 308. In the embodiment, the operation slot 305 is defined in a bottom of the hard disk drive 300, extending through the front wall 301.

The bracket 20 is a rectangular shell, and includes a bottom wall 21, two sidewalls 23 perpendicularly extending up from two opposite sides of the bottom wall 21, two positioning plates 24 perpendicularly extending up from the bottom wall 21 between and parallel to the sidewalls 23, and an end plate 25 perpendicularly extending up from the bottom wall 21 and connected between rear ends of the positioning plates 24. The bottom wall 21, the positioning plates 24, and the end plate 25 cooperatively bound a receiving space 212. Each sidewall 23 and an adjacent positioning plate 24 bound a long slot 214. The end plate 25 defines an opening 252 communicating with the receiving space 212, and two screw holes 254 at two opposite sides of the opening 252. Each positioning plate 24 defines two spaced through holes 242 communicating with the receiving space 212 and the corresponding slot 214, and a plurality of fastening holes 249 adjacent to the end plate 25. Each sidewall 23 defines two fixing holes 232.

Each latching member 40 includes a long resilient piece 41, a hook 42 extending in from a first end of the piece 41, and two positioning pins 48 perpendicularly extending in from the piece 41. A second end of each piece 41 defines a plurality of connecting holes 46, opposite to the first end. A surface of the hook 42 opposite to the second end of the piece 41 forms a slanted guiding surface 44.

The switching member 60 includes a main body 62, a first connector 64 extending from a front side surface of the main body 62, and a second connector 66 extending from a rear side surface of the main body 62 opposite to the first connector 64. Two opposite ends of the main body 62 each define a through hole 68. The second connector 66 is electrically connected to a motherboard (not shown) in the casing 200.

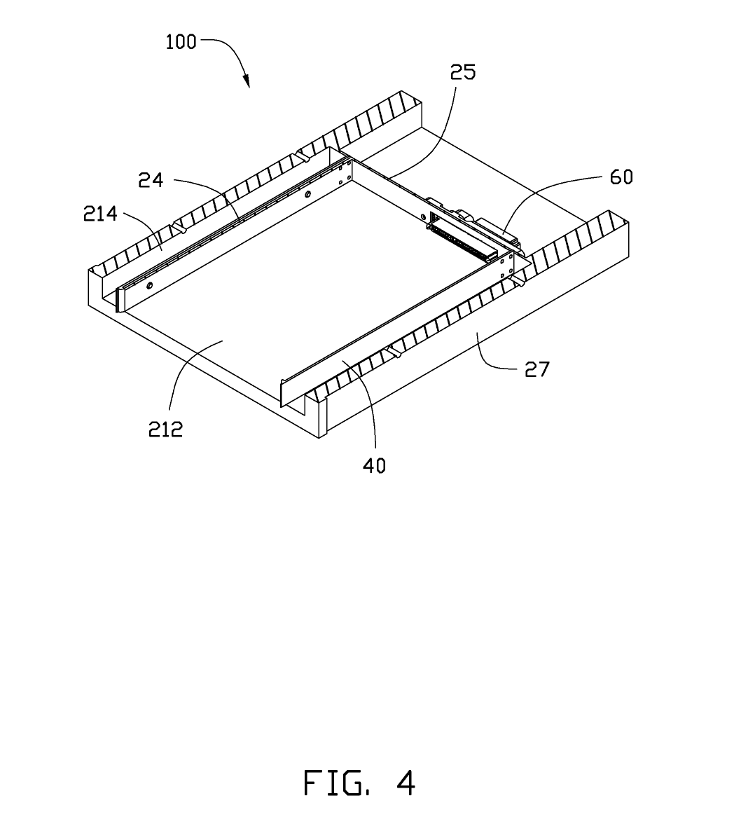

Referring to FIG. 4, in assembly of the mounting apparatus 100, each latching member 40 is inserted into a corresponding slot 214. The positioning pins 48 extend into the receiving space 212 through the corresponding through holes 242. The hook 44 is located outside the bracket 20. Rivets extend through the connecting holes 46 and the fastening holes 249. The first connector 64 is extended through the opening 252 from an outer side of the end plate 25. The main body 62 abuts against an outer surface of the end plate 25. Two screws extend through the through holes 68, to be screwed into the corresponding screw holes 254.

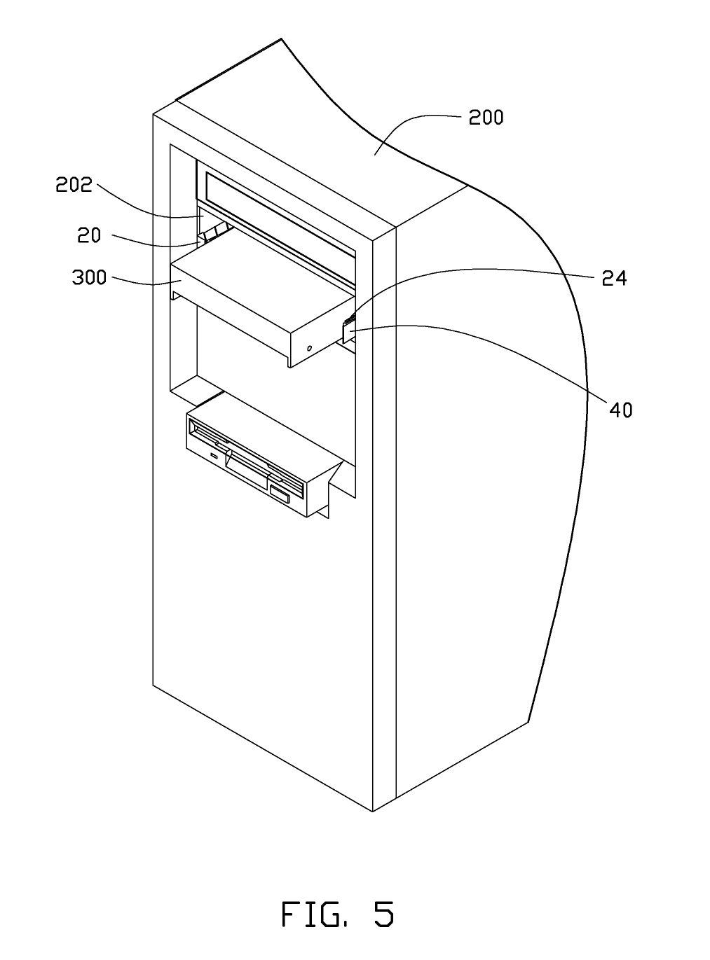

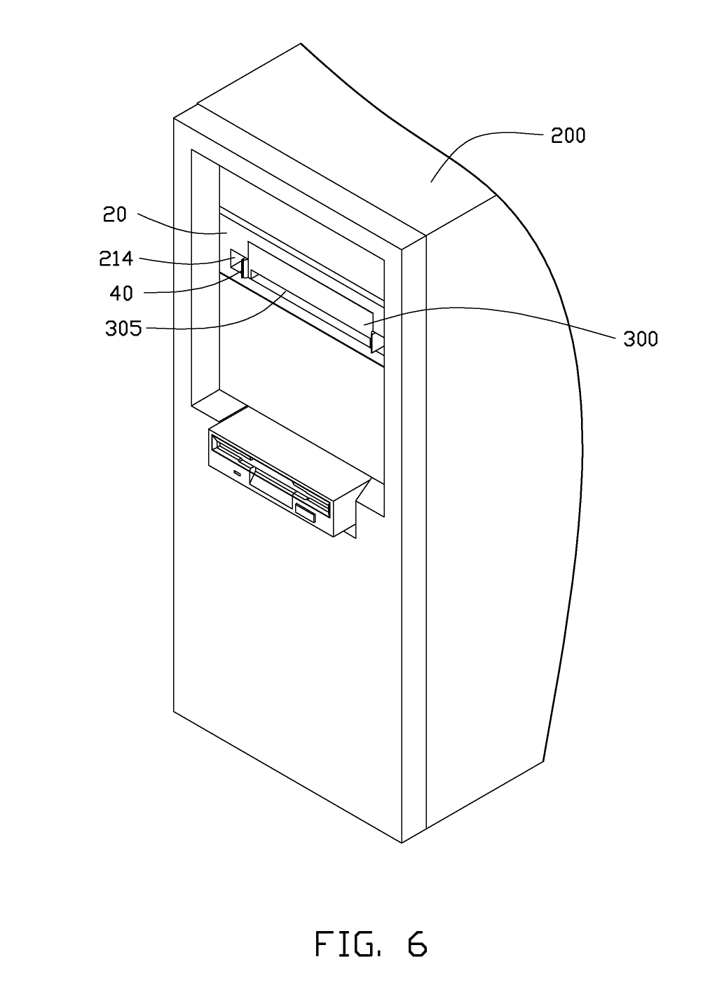

Referring to FIGS. 5-6, in assembly of the mounting apparatus 100 to the casing 200, the bracket 20 is inserted into the expansion bay 202 from the front panel 201. A plurality of screws extends through the casing 200, to be screwed into the corresponding fixing holes 232, thereby mounting the bracket 20 in the expansion bay 202.

To mount the hard disk drive 300 to the bracket 100, the connector 306 aligns with the first connector 64. The hard disk drive 300 is slidably inserted into the receiving space 212. The side plates 304 slidably abut against the corresponding guiding surfaces 44, deforming the pieces 41, to allow the hooks 42 to move away from each other. Therefore, the positioning pins 48 are moved away from the receiving space 212 and withdrawn in the corresponding through holes 242. After the front wall 301 passes over the hooks 42, the pieces 41 are restored to bias the hooks 42 to block the front wall 301. The positioning pins 48 extend through the through holes 242, to be inserted into the corresponding connecting holes 308. The connector 306 is engaged in the first connector 64, thereby electrically connecting the hard disk drive 300 to the motherboard of the casing 200.

To detach the hard disk drive 300 from the mounting apparatus 100, the hooks 42 are pulled away from each other, to deform the pieces 41, until the hooks 42 disengage from the front wall 301. The positioning pins 48 are disengaged from the corresponding connecting holes 308. The hard disk drive 300 can be pulled away from the receiving space 212 by fingers inserted into the operation slot 305 and moving the hard disk drive 300. The connector 306 is disengaged from the first connector 64. Therefore, the hard disk drive 300 can be easily detached from the mounting apparatus 100.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A mounting apparatus for a hard disk drive, comprising:
a bracket comprising two opposite positioning plates and an end plate connected between rear ends of the positioning plates, the positioning plates and the end plate cooperatively bounding a receiving space for receiving the hard disk drive, the receiving space extending through a front end of the bracket opposite to the end plate;
a resilient latching member comprising a first end mounted to an outer side surface of one of the positioning plate, and a second end opposite to the first end and extending outside the bracket through the front end of the bracket, the second end detachably to be latched to the hard disk drive; and
a connector fixed to the end plate to connect the hard disk drive.

2. The mounting apparatus of claim 1, wherein a hook extends out from the second end of the latching member to block a front end of the hard disk drive.

3. The mounting apparatus of claim 2, wherein a side surface of the hook opposite to the first end of the piece forms a slanted guiding surface, when the hard disk drive enters the bracket, the hard disk drive abuts against the guiding surface to deform the piece outward.

4. The mounting apparatus of claim 1, wherein each positioning plate defines a through hole, a positioning pin protrudes from the latching member and extends through the through hole to latch the hard disk drive.

5. The mounting apparatus of claim 1, wherein the bracket further comprises a bottom wall, and two sidewalls extending up from two opposite sides of the bottom wall, the positioning plates are located between and parallel to the sidewalls, a sidewall and the corresponding positioning plate cooperatively bound a slot for receiving the latching member.

6. The mounting apparatus of claim 1, wherein the end plate defines an opening through which the connecter extends.

7. An electronic device comprising:
a casing defining a expansion bay and comprising a front panel, the expansion bay extending through the front panel; and
a mounting apparatus mounted within the expansion bay, and comprising:
a bracket defining a receiving space extending through a front end of the bracket;
a resilient latching member comprising a first end mounted to the bracket, and a second end extending outside the bracket through the front end of the bracket; and
a connector mounted to a rear end of the bracket opposite to the front end; wherein a hard disk drive is operable to enter the receiving space through the front panel by deforming the latching member away from the hard disk drive, after the hard disk drive is completely received in the receiving space, the latching member is restored to block a front end of the hard disk drive by the second end of the latching member, a rear end of the hard disk drive is connected to the connector.

8. The electronic device of claim 7, wherein a hook extends from the second end of the latching member to block the hard disk drive.

9. The electronic device of claim 7, wherein the bracket comprises a bottom wall, two positioning plates extending up from two opposite sides of the bottom wall, and an end plate connected between rear ends of the positioning plates, the positioning plates and the end plate cooperatively bound the receiving space, the first end of the latching member is mounted to an outer side surface of a corresponding positioning plate, the connector is fixed to the end plate.

10. The electronic device of claim 9, wherein the positioning plate fixing the latching member defines two through holes, two positioning pins extend from the latching member and extend through the through holes to latch into the hard disk drive.

11. The electronic device of claim 9, wherein the bracket further comprises two sidewalls extending up from two opposite sides of the bottom wall adjacent to the positioning plates, each positioning plate and the corresponding side plate cooperatively bound a slot, the slot bounded by the positioning plate fixing the latching slot and the corresponding side plate receives the latching member.
